(19) United States
(12) Patent Application Publication
(10) Pub. No.: US 2023/0197767 A1
(43) Pub. Date: Jun. 22, 2023

(54) HYBRID BONDED CAPACITORS

(71) Applicant: Intel Corporation, Santa Clara, CA (US)

(72) Inventor: Changyok PARK, Portland, OR (US)

(21) Appl. No.: 17/557,557

(22) Filed: Dec. 21, 2021

(51) Int. Cl. H01L 49/02; H01L 23/495; H01L 23/492

(52) U.S. Cl. CPC H01L 28/55; H01L 23/4924; H01L 23/49513

(57) ABSTRACT

Embodiments herein relate to systems, apparatuses, or processes for forming a decoupling capacitor within a multilayer die using hybrid bonding. Dummy bond pads may be used to form plates for the capacitor and a high-k dielectric material may be deposited between the plates prior to hybrid bonding. Other embodiments may be described and/or claimed.

### FIELD

Embodiments of the present disclosure generally relate to the field of package assemblies, and in particular decoupling capacitors within package substrates.

### BACKGROUND

Continued reduction in end-product size of mobile electronic devices such as smart phones and ultrabooks, and increased performance requirements, are driving the miniaturization and increased power management capabilities of packages within these devices.

### BRIEF DESCRIPTION OF THE DRAWINGS

FIG. 1 illustrates a cross section side view of a package that includes a hybrid bonded capacitor, in accordance with various embodiments.

FIG. 2 illustrates cross section top-down views of packages that include example capacitor plate layouts for hybrid bonded capacitors, in accordance with various embodiments.

FIGS. 3A-3P illustrate stages in a manufacturing process for creating hybrid bonded capacitors, in accordance with various embodiments.

FIGS. 4A-4B schematically illustrate a top view of an example die in wafer form and in singulated form, and a cross section side view of a package assembly, in accordance with various embodiments.

FIG. 5 illustrates an example of a process for creating a hybrid bonded capacitor, in accordance with various embodiments.

FIG. 6 schematically illustrates a computing device, in accordance with embodiments.

### DETAILED DESCRIPTION

Embodiments of the present disclosure may generally relate to systems, apparatus, and/or processes directed to forming a capacitor, in particular a decoupling capacitor, within a multilayer substrate, one or more substrates within a silicon die, or a multilayer die, using hybrid bonding. In embodiments, dummy bond pads may be used to form part or all of the capacitor, where dummy bond pads are not connected to any signal. In embodiments, a dielectric material of the capacitor may include a high-k dielectric material such as, but not limited to, hafnium or zirconium.

In embodiments, a plurality of capacitors may be formed within the multilayer substrate, and may help with ground bounce during operations of high-performance circuits within the multilayer substrate or coupled with the multilayer substrate to enable higher product performance.

In embodiments, dummy bond pads within a multilayer substrate may have a smaller width than that of an active bond pad. As a result, embodiments described herein formed using dummy bond pads may provide a capacitor that may be placed at several locations within the multilayer substrate. In embodiments, once dummy bond pads are formed, they may be connected to a postive voltage reference (e.g., a voltage rail such as Voltage drain drain (Vdd)) or a negative voltage or ground reference (e.g., a ground rail such as Voltage source souce (Vss)) using either bond pad layers to connect directly with Vdd or Vss pads, or may be connected using routing within the multilayer substrate to route down to an underlying layer, and back up to connect with Vdd or Vss pads.

In embodiments, the multilayer substrate may be formed by creating two dies with dummy bond pads at a top layer of the dies, and then forming the multilayer substrate by hybrid bonding the two dies together. In embodiments, dummy bond pads of the top die or a bottom die may be recessed, and then a dielectric material, in particular a high-k dielectric material, may be placed on top of the recessed dummy bond pads before the top and bottom dies are hybrid bonded together. In embodiments, this manufacturing process may be used to form high capacitance decoupling capacitors, which may provide extra capacitance in areas ordinarily unused within the multilayer dies. This manufacturing process may be performed by adding a few extra steps on top of a regular bond pad forming process as described further below.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

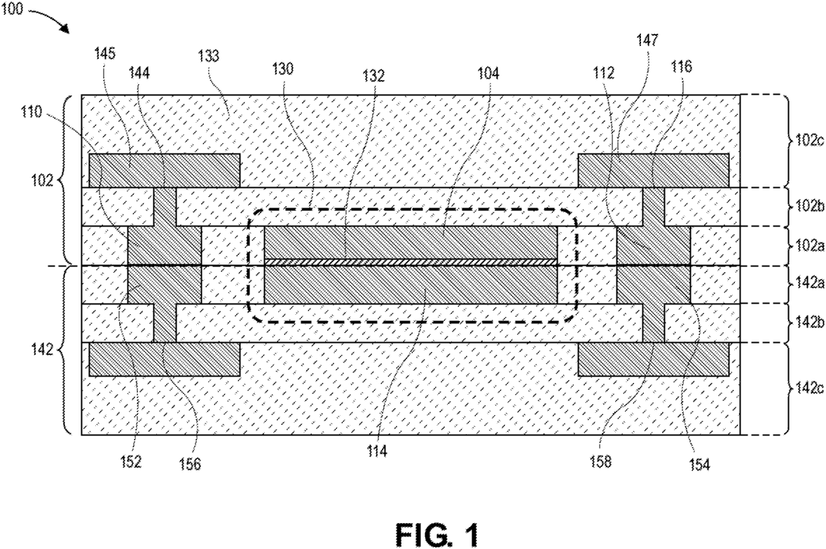

FIG. 1 illustrates a cross section side view of a package that includes a hybrid bonded capacitor, in accordance with various embodiments. Package 100 shows an example of a first die 102 that may be bonded to a second die 142 using a hybrid bonding process. A bonding pad 104 of the first die 102 maybe coupled with a dielectric layer 132, and a bonding pad 114 of the second die 142 may also be coupled with the dielectric layer 132. As a result, a capacitor 130 may be formed by the bonding pad 104, the dielectric layer 132, and the bonding pad 114. In embodiments, the resulting capacitor 130 may be a decoupling capacitor. In embodiments, non-metal layers as described further below may include a dielectric material 133.

In embodiments, the first die 102 may include substrates 102a, 102b, 102c, and the second die 142 may include substrates 142a, 142b, 142c. Bonding pad 104 may be within the substrate 102a, and a bonding pad 114 may be within the substrate 142a. In embodiments, there may be other features, including electrical routing features, within the first die 102 and the second die 142. In particular, these may include metal layers 110, 112 within the substrate 102a, and metal layers 152, 154 within substrate 142a.

In addition, other electrical routing features may be within multilayer substrate 100, including metal structure 144 within layers 102b, 102c that may be electrically coupled with the metal layer 110, and metal structure 116 within layers 102b, 102c that may be electrically coupled with the metal layer 112. Similarly, metal structure 156 within layers 142b, 142c may be physically and electrically coupled with the metal layer 152, and metal structure 158 within layers 142b, 142c may be physically and electrically coupled with the metal layer 154.

During a hybrid bonding process, metal layers 110, 152 may be directly physically and electrically coupled, and metal layers 112, 154 may be directly physically and electrically coupled. In embodiments, the metal layers 110, 152 may be electrically coupled with a Vss pad 145, and the metal layers 112, 154 may be electrically coupled with a Vdd pad 147.

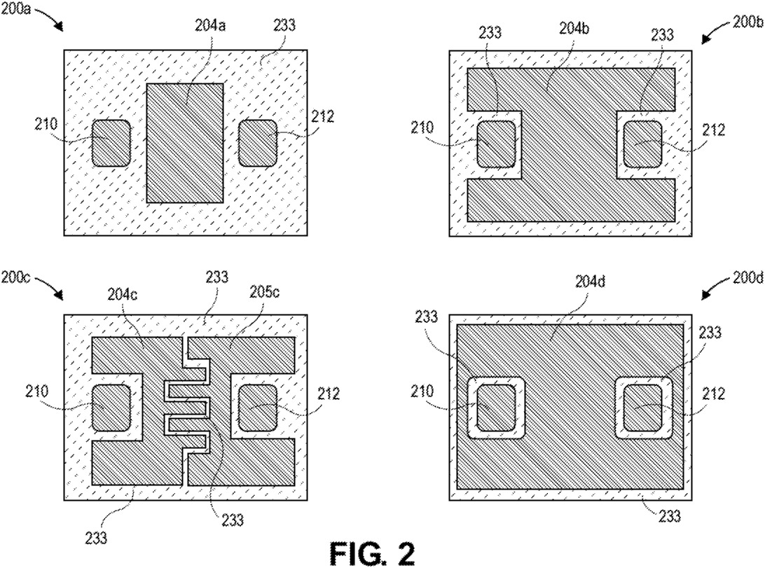

FIG. 2 illustrates cross section top-down views of packages that include example capacitor plate layouts for hybrid bonded capacitors, in accordance with various embodiments. In embodiments, the various capacitor plate layouts, which are nonexclusive example set of layouts, may be designed based upon the various routing features and/or capacitive requirements from the capacitor, which may be similar to capacitor 130 of FIG. 1.

Package 200a shows a top-down cross section view that shows capacitor metal layer 204a and metal layers 210, 212, which may be similar to bonding pad 104 and metal layers 110, 112 of FIG. 1., that may be connected, respectively, to a Vdd or Vss, The capacitor metal layer 204a is in a substantially rectangular position as shown. In embodiments, the dielectric layer 132 may be directly beneath the capacitor layer 204a, and the second capacitor metal layer, such as bonding pad 114 of FIG. 1, may be beneath capacitor layer 204a. Surrounding the metal layers 204a, 210, 212 may be a dielectric layer 233, which may be similar to dielectric layer 133 of FIG. 1. In embodiments, the dielectric layer 233 may be different than the dielectric layer 132 of FIG. 1

Package 200b shows another top-down cross section example where capacitor metal layer 204b, which may be similar to capacitor metal layer 204a, wraps partially around the metal layers 210, 212, and provides additional surface area as compared to capacitor metal layer 204a. As shown, a dielectric layer 233 may electrically isolate the capacitive metal layer 204b from the metal layer 210, and/or from the metal layer 212.

Package 200c shows another top-down cross section example where capacitor metal layers 204c, 205c, which may be similar to capacitor metal layer 204b, are in a comb-type configuration that wraps partially around the metal layers 210, 212. In this embodiment, metal layers 204c and 205c are from two different capacitors, and provide two capacitors within an embodiment that may be similar to package 100 of FIG. 1. As shown, a dielectric layer 233 may electrically isolate the capacitive metal layers 204c, 205c from the metal layer 210, and/or from the metal layer 212. In embodiments, capacitive metal layers 204c, 205c may be connected to opposite polarity of power (Vdd vs Vss) to maximize capacitance.

Package 200d shows another top-down cross section example where capacitor metal layer 204d, which may be similar to capacitor metal layer 204b, wraps completely around the metal layers 210, 212. This configuration provides additional surface area as compared to capacitor metal layer 204b. As shown, a dielectric layer 233 may electrically isolate the capacitive metal layer 204d from the metal layer 210, and/or from the metal layer 212.

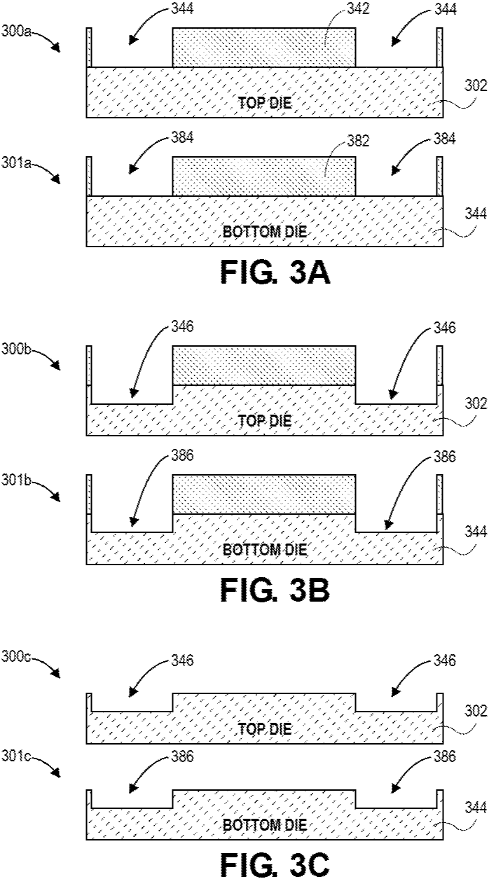

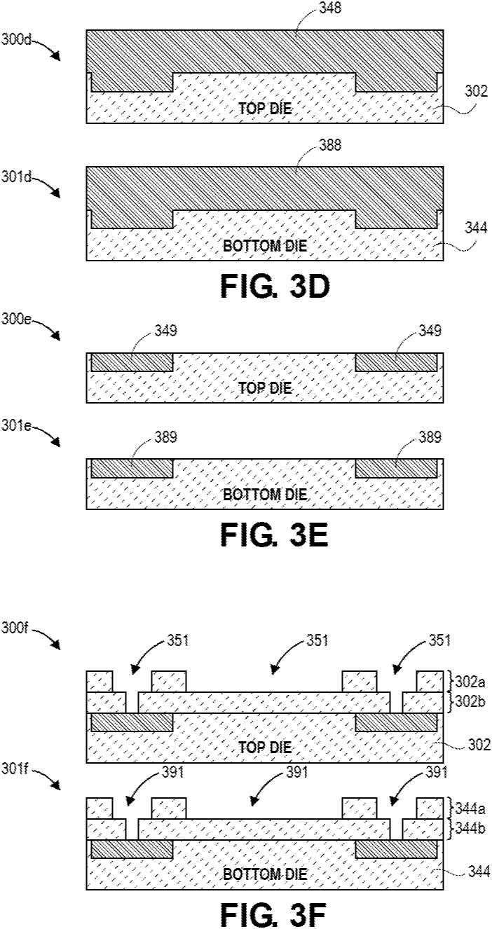

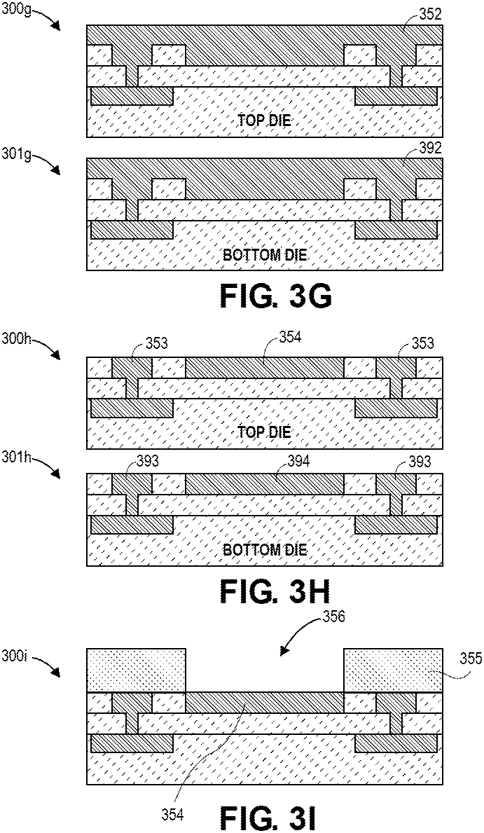

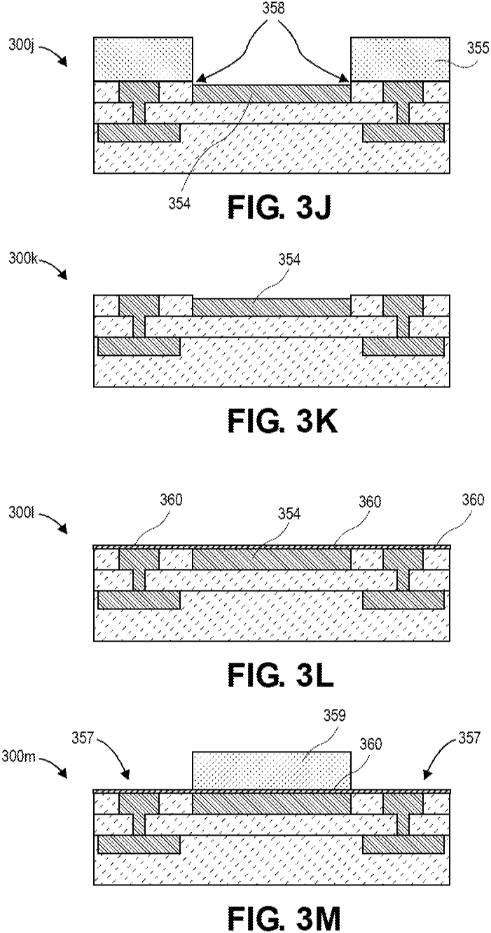

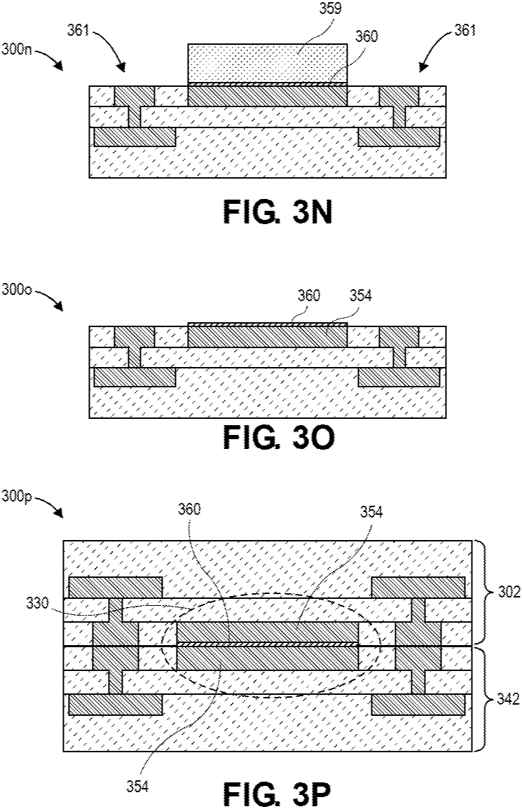

FIGS. 3A-3P illustrate stages in a manufacturing process for creating hybrid bonded capacitors, in accordance with various embodiments. FIG. 3A shows a stage in the manufacturing process that includes a first die 300a and a second die 301a, which may be similar to first die 102 and second die 142 of FIG. 1, where substrate layers 302, 344 are provided. Photoresist layers 342, 382 are placed, respectively, on the substrate layers 302, 344. Lithographic exposure/development is then performed to form the cavities 344, 384. In embodiments, the substrate layers 302, 344 may be dielectric layers.

FIG. 3B shows a stage in the manufacturing process that includes a first die 300b and a second die 301b, which may be similar to first die 102 and second die 142 of FIG. 1, where an etch is performed to create cavities 346 and 386, respectively, in substrate layers 302, 344. In embodiments, these cavities 346, 386 define a bond pad layer.

FIG. 3C shows a stage in the manufacturing process that includes a first die 300c and a second die 301c, which may be similar to first die 102 and second die 142 of FIG. 1, where the photoresist 342, 382 is removed.

FIG. 3D shows a stage in the manufacturing process that includes a first die 300d and a second die 301d, which may be similar to first die 102 and second die 142 of FIG. 1, where metal 348, 388 is deposited on substrate layers 302, 344, and filling cavities 346, 386. In embodiments, copper may be deposited. In embodiments, the deposition may be performed by an electroplating process.

FIG. 3E shows a stage in the manufacturing process that includes a first die 300e and a second die 301e, which may be similar to first die 102 and second die 142 of FIG. 1, where metal 348, 388 is etched and/or polished, for example by using a chemical metal polish (CMP) process. This leaves metal pads 349, 389.

FIG. 3F shows a stage in the manufacturing process that includes a first die 300f and a second die 301f, which may be similar to first die 102 and second die 142 of FIG. 1, where additional layers 302a, 302b, which may be placeholders for a bond pad layer and an underlying via layer, are placed on top of layer 302, an additional layers 344a, 344b are placed on top of layer 344. In embodiments, each of these layers may be etched, such that the resulting cavities 351, 391 are formed. In embodiments, the additional layers 302a, 302b, 344a, 344b may be a dielectric. It should be noted that at this manufacturing stage, one or more additional routing features (not shown) may be included into additional layers 302a, 344a, for subsequent patterning.

FIG. 3G shows a stage in the manufacturing process that includes a first die 300g and a second die 301g, which may be similar to first die 102 and second die 142 of FIG. 1, where metal 352, 392 is deposited on substrate layers 302a, 302b, 344a, 344b, and fills cavities 351, 391. In embodiments, copper may be deposited.

FIG. 3H shows a stage in the manufacturing process that includes a first die 300h and a second die 301h, which may be similar to first die 102 and second die 142 of FIG. 1, where metal 352, 392 is etched and/or polished, for example by using a chemical metal polish (CMP) process. This leaves metal structures 353, 354, 393, 394. Note that in embodiments, metal structures 354, 394 may be similar to bonding pad 104 and bonding pad 114 of FIG. 1.

FIG. 3I shows a stage in the manufacturing process that includes a die 300i, which may be similar to first die 102 and/or second die 142 of FIG. 1, where a photoresist layer 355 is applied, and a cavity 356 is etched through the photoresist layer 355 to expose the metal structure 354.

FIG. 3J shows a stage in the manufacturing process that includes a die 300j, which may be similar to first die 102 and/or second die 142 of FIG. 1, where a copper etch may be performed to create a cavity 358 within the copper layer 354. In embodiments, a depth of the cavity 358 may be determined based on a desired thickness of a high-k dielectric, such as dielectric 132 of FIG. 1. In embodiments, the copper etch may be performed using, for example, reactive ion etching, or wet etching. Note that in embodiments, only one of the first die 102 or the second die 142 may include the copper etch.

FIG. 3K shows a stage in the manufacturing process that includes a die 300k, which may be similar to first die 102 and/or second die 142 of FIG. 1, where the photoresist layer 355 is removed, keeping the copper layer 354 exposed.

FIG. 3L shows a stage in the manufacturing process that includes a die 300l, which may be similar to first die 102 and/or second die 142 of FIG. 1, where a dielectric layer 360, which may be similar to dielectric layer 132 of FIG. 1, is deposited. In embodiments, the dielectric layer 360 is deposited within the cavity 358 above the copper layer 354.

FIG. 3M shows a stage in the manufacturing process that includes a die 300m, which may be similar to first die 102 and/or second die 142 of FIG. 1, where photoresist layer 359 is applied, and cavities 357 subsequently etched, so that the photoresist layer 359 is above the dielectric layer 360.

FIG. 3N shows a stage in the manufacturing process that includes a die 300n, which may be similar to first die 102 and/or second die 142 of FIG. 1, where the dielectric layer 360 is removed leaving clear areas 361. Note that the dielectric layer 360 now only exist below the photoresist 359

FIG. 3O shows a stage in the manufacturing process that includes a die 300o, which may be similar to first die 102 and/or second die 142 of FIG. 1, where the photoresist 359 is removed, exposing the dielectric layer 360 that is above the metal layer 354.

FIG. 3P shows a stage in the manufacturing process that includes a package 300p, which may be similar to package 100 of FIG. 1, where a first die 302, which may be similar to first die 102 of FIG. 1 and may be similar to die 300o of FIG. 3O, is hybrid bonded to a second die 342, which may be similar to second die 142 of FIG. 1 and may be similar to die 300o of FIG. 3O. The dielectric 360 is between metal layers 354, which may be similar to bonding pads 104, 114 of FIG. 1. As a result, a capacitor 330 is formed.

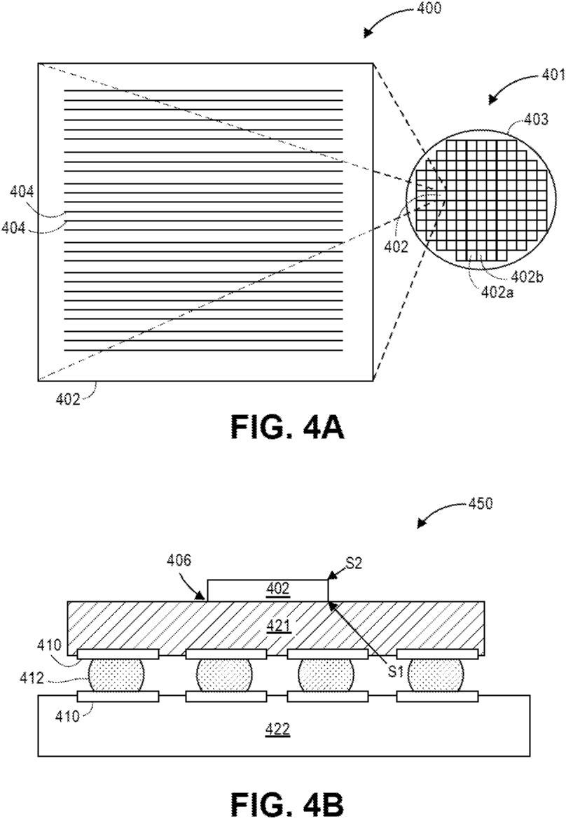

FIGS. 4A-4B schematically illustrate a top view of an example die in wafer form and in singulated form, and a cross section side view of a package assembly, in accordance with various embodiments. FIG. 4A schematically illustrates a top view of an example die 402 in a wafer form 401 and in a singulated form 400, in accordance with some embodiments. In some embodiments, die 402 may be one of a plurality of dies, e.g., dies 402, 402a, 402b, of a wafer 403 comprising semiconductor material, e.g., silicon or other suitable material. The plurality of dies, e.g., dies 402, 402a, 402b, may be formed on a surface of wafer 403. Each of the dies 402, 402a, 402b, may be a repeating unit of a semiconductor product that includes devices as described herein. For example, die 402 may include circuitry having transistor elements such as, for example, one or more channel bodies 404 (e.g., fin structures, nanowires, and the like) that provide a channel pathway for mobile charge carriers in transistor devices. Although one or more channel bodies 404 are depicted in rows that traverse a substantial portion of die 402, it is to be understood that one or more channel bodies 404 may be configured in any of a wide variety of other suitable arrangements on die 402 in other embodiments.

After a fabrication process of the device embodied in the dies is complete, wafer 403 may undergo a singulation process in which each of dies, e.g., die 402, is separated from one another to provide discrete “chips” of the semiconductor product. Wafer 403 may be any of a variety of sizes. In some embodiments, wafer 403 has a diameter ranging from about 25.4 mm to about 450 mm. Wafer 403 may include other sizes and/or other shapes in other embodiments. According to various embodiments, the one or more channel bodies 404 may be disposed on a semiconductor substrate in wafer form 401 or singulated form 400. One or more channel bodies 404 described herein may be incorporated in die 402 for logic, memory, or combinations thereof. In some embodiments, one or more channel bodies 404 may be part of a system-on-chip (SoC) assembly.

FIG. 4B schematically illustrates a cross-section side view of an integrated circuit (IC) assembly 450, in accordance with some embodiments. In some embodiments, IC assembly 450 may include one or more dies, e.g., die 402, hybrid bonded using techniques described herein to package substrate 421. Die 402 may include one or more channel bodies 404 that serve as channel bodies of multi-threshold voltage transistor devices. In some embodiments, package substrate 421 may be electrically coupled with a circuit board 422 as is well known to a person of ordinary skill in the art. Die 402 may represent a discrete product made from a semiconductor material (e.g., silicon) using semiconductor fabrication techniques such as thin film deposition, lithography, etching, and the like used in connection with forming Complementary Metal Oxide Semiconductor (CMOS) devices. In some embodiments, die 402 may be, include, or be a part of a processor, memory, SoC or ASIC in some embodiments.

Die 402 can be attached to package substrate 421 according to a wide variety of suitable configurations including, for example, being directly coupled with package substrate 421 in a flip-chip configuration, as depicted. In the flip-chip configuration, an active side S1 of die 402 including circuitry is attached to a surface of package substrate 421 using hybrid bonding structures as described herein that may also electrically couple die 402 with package substrate 421. Active side S1 of die 402 may include multi-threshold voltage transistor devices as described herein. An inactive side S2 of die 402 may be disposed opposite to active side S1.

In some embodiments, package substrate 421 is an epoxy-based laminate substrate having a core and/or build-up layers such as, for example, an Ajinomoto Build-up Film (ABF) substrate. Package substrate 421 may include other suitable types of substrates in other embodiments including, for example, substrates formed from glass, ceramic, or semiconductor materials.

Package substrate 421 may include electrical routing features configured to route electrical signals to or from die 402. The electrical routing features may include pads or traces (not shown) disposed on one or more surfaces of package substrate 421 and/or internal routing features (not shown) such as trenches, vias, or other interconnect structures to route electrical signals through package substrate 421. In some embodiments, package substrate 421 may include electrical routing features such as pads (not shown) configured to receive the respective die-level interconnect structures 406 of die 402.

Circuit board 422 may be a printed circuit board (PCB) comprising an electrically insulative material such as an epoxy laminate. Circuit board 422 may include electrically insulating layers composed of materials such as, for example, polytetrafluoroethylene, phenolic cotton paper materials such as Flame Retardant 4 (FR-4), FR-1, cotton paper and epoxy materials such as CEM-1 or CEM-3, or woven glass materials that are laminated together using an epoxy resin prepreg material. Interconnect structures such as traces, trenches, vias may be formed through the electrically insulating layers to route the electrical signals of die 402 through circuit board 422. Circuit board 422 may comprise other suitable materials in other embodiments. In some embodiments, circuit board 422 is a motherboard as is well known to a person of ordinary skill in the art.

Package-level interconnects such as, for example, solder balls 412 may be coupled to one or more pads 410 on package substrate 421 and/or on circuit board 422 to form corresponding solder joints that are configured to further route the electrical signals between package substrate 421 and circuit board 422. Pads 410 may comprise any suitable electrically conductive material such as metal including, for example, nickel (Ni), palladium (Pd), gold (Au), silver (Ag), copper (Cu), and combinations thereof. Other suitable techniques to physically and/or electrically couple package substrate 421 with circuit board 422 may be used in other embodiments.

IC assembly 450 may include a wide variety of other suitable configurations in other embodiments including, for example, suitable combinations of flip-chip and/or wire-bonding configurations, interposers, multi-chip package configurations including system-in-package (SiP), and/or package-on-package (PoP) configurations. Other suitable techniques to route electrical signals between die 402 and other components of IC assembly 450 may be used in some embodiments.

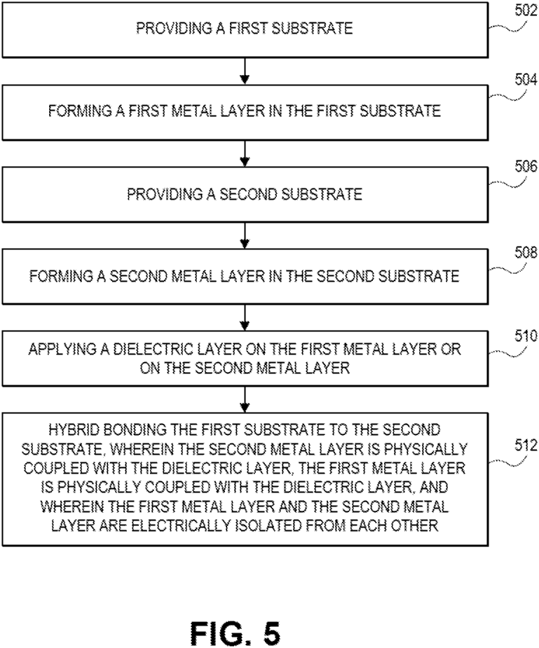

FIG. 5 illustrates an example of a process for building a decoupling capacitor with hybrid bonding process in accordance with embodiments. Process 500 may be performed by one or more elements, techniques, or systems that may be described herein, and in particular with respect to FIGS. 1-4.

At block 502, the process may include providing a first substrate. In embodiments, the first substrate may be similar to substrate 102 or substrate 142 of FIG. 1.

At block 504, the process may further include forming a first metal layer in the first substrate. In embodiments, the first metal layer may be similar to metal pad 104 or metal pad 114 of FIG. 1.

At block 506, the process may further include providing a second substrate. In embodiments, the second substrate may be similar to substrate 142 or substrate 102 of FIG. 1.

At block 508, the process may further include forming a second metal layer in the second substrate. In embodiments, the second metal layer may be similar to metal pad 114 or metal pad 104 of FIG. 1.

At block 510, the process may further include applying a dielectric layer on the first metal layer or on the second metal layer. In embodiments, the dielectric layer may be similar to dielectric layer 132 of FIG. 1.

At block 512, the process may further include hybrid bonding the first substrate to the second substrate, wherein the second metal layer is physically coupled with the dielectric layer, the first metal layer is physically coupled with the dielectric layer, and wherein the first metal layer and the second metal layer are electrically isolated from each other. In embodiments, the result of this process may include capacitor 130 of FIG. 1.

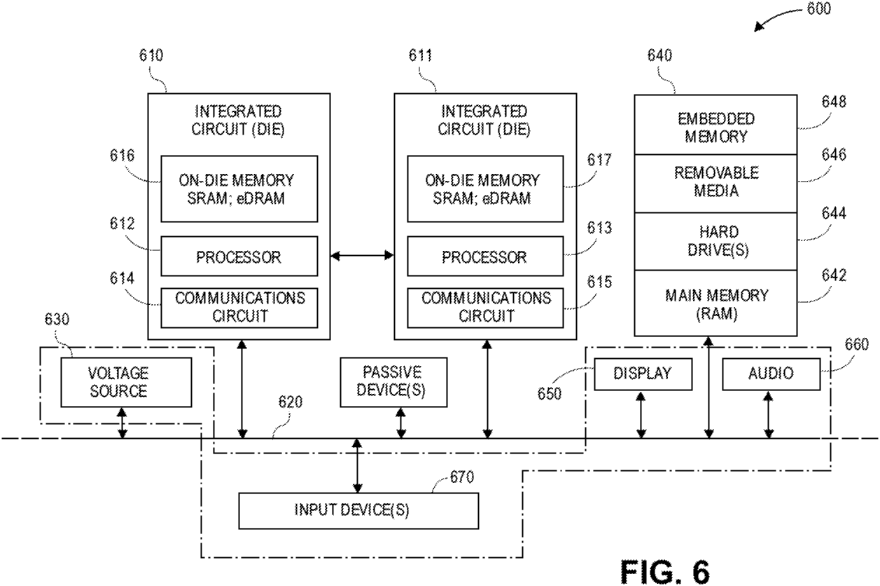

FIG. 6 is a schematic of a computer system 600, in accordance with an embodiment of the present invention. The computer system 600 (also referred to as the electronic system 600) as depicted can embody a hybrid bonded capacitor, according to any of the several disclosed embodiments and their equivalents as set forth in this disclosure. The computer system 600 may be a mobile device such as a netbook computer. The computer system 600 may be a mobile device such as a wireless smart phone. The computer system 600 may be a desktop computer. The computer system 600 may be a hand-held reader. The computer system 600 may be a server system. The computer system 600 may be a supercomputer or high-performance computing system.

In an embodiment, the electronic system 600 is a computer system that includes a system bus 620 to electrically couple the various components of the electronic system 600. The system bus 620 is a single bus or any combination of busses according to various embodiments. The electronic system 600 includes a voltage source 630 that provides power to the integrated circuit 610. In some embodiments, the voltage source 630 supplies current to the integrated circuit 610 through the system bus 620.

The integrated circuit 610 is electrically coupled to the system bus 620 and includes any circuit, or combination of circuits according to an embodiment. In an embodiment, the integrated circuit 610 includes a processor 612 that can be of any type. As used herein, the processor 612 may mean any type of circuit such as, but not limited to, a microprocessor, a microcontroller, a graphics processor, a digital signal processor, or another processor. In an embodiment, the processor 612 includes, or is coupled with, a hybrid bonded capacitor, as disclosed herein. In an embodiment, SRAM embodiments are found in memory caches of the processor. Other types of circuits that can be included in the integrated circuit 610 are a custom circuit or an application-specific integrated circuit (ASIC), such as a communications circuit 614 for use in wireless devices such as cellular telephones, smart phones, pagers, portable computers, two-way radios, and similar electronic systems, or a communications circuit for servers. In an embodiment, the integrated circuit 610 includes on-die memory 616 such as static random-access memory (SRAM). In an embodiment, the integrated circuit 610 includes embedded on-die memory 616 such as embedded dynamic random-access memory (eDRAM).

In an embodiment, the integrated circuit 610 is complemented with a subsequent integrated circuit 611. Useful embodiments include a dual processor 613 and a dual communications circuit 615 and dual on-die memory 617 such as SRAM. In an embodiment, the dual integrated circuit 610 includes embedded on-die memory 617 such as eDRAM.

In an embodiment, the electronic system 600 also includes an external memory 640 that in turn may include one or more memory elements suitable to the particular application, such as a main memory 642 in the form of RAM, one or more hard drives 644, and/or one or more drives that handle removable media 646, such as diskettes, compact disks (CDs), digital variable disks (DVDs), flash memory drives, and other removable media known in the art. The external memory 640 may also be embedded memory 648 such as the first die in a die stack, according to an embodiment.

In an embodiment, the electronic system 600 also includes a display device 650, an audio output 660. In an embodiment, the electronic system 600 includes an input device such as a controller 670 that may be a keyboard, mouse, trackball, game controller, microphone, voice-recognition device, or any other input device that inputs information into the electronic system 600. In an embodiment, an input device 670 is a camera. In an embodiment, an input device 670 is a digital sound recorder. In an embodiment, an input device 670 is a camera and a digital sound recorder.

As shown herein, the integrated circuit 610 can be implemented in a number of different embodiments, including a package substrate having a hybrid bonded capacitor, according to any of the several disclosed embodiments and their equivalents, an electronic system, a computer system, one or more methods of fabricating an integrated circuit, and one or more methods of fabricating an electronic assembly that includes a package substrate having a hybrid bonded capacitor, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed package substrates having a hybrid bonded capacitor embodiments and their equivalents. A foundation substrate may be included, as represented by the dashed line of FIG. 6. Passive devices may also be included, as is also depicted in FIG. 6.

### EXAMPLES

The following paragraphs describe examples of various embodiments.

Example 1 is a capacitor comprising: a first substrate; a first metal layer in the first substrate; a second substrate; a second metal layer in the second substrate; and a dielectric layer between the first metal layer and the second metal layer, wherein the first metal layer and the dielectric layer are in direct physical contact, the second metal layer and the dielectric layer are in direct physical contact, and wherein the first metal layer and the second layer are electrically isolated from each other.

Example 2 may include the capacitor of example 1, or of any other example or embodiment described herein, wherein the dielectric layer is on the first metal layer in the first substrate.

Example 3 may include the capacitor of example 2, or of any other example or embodiment described herein, wherein a portion of the dielectric layer is on the first metal layer in the first substrate, and wherein another portion of the dielectric layer is on the second metal layer in the second substrate.

Example 4 may include the capacitor of example 1, or of any other example or embodiment described herein, wherein the first substrate and the second substrate are hybrid bonded.

Example 5 may include the capacitor of example 1, or of any other example or embodiment described herein, wherein the dielectric is a high-k dielectric.

Example 6 may include the capacitor of example 1, or of any other example or embodiment described herein, wherein the dielectric layer has a thickness ranging from 3 µm to 10 µm.

Example 7 may include the capacitor of example 1, or of any other example or embodiment described herein, wherein the first substrate includes a selected one of: silicon or glass.

Example 8 may include the capacitor of example 1, or of any other example or embodiment described herein, wherein the first metal layer in the first substrate extends from a first side of the first substrate to a second side of the first substrate opposite the first side of the first substrate.

Example 9 may include the capacitor of example 1, or of any other example or embodiment described herein, wherein the first metal layer and the second metal layer overlap with respect to a direction perpendicular to a plane of a side of the first substrate.

Example 10 may include the capacitor of example 1, or of any other example or embodiment described herein, wherein the first metal layer or the second metal layer are dummy bond pads.

Example 11 may include the capacitor of example 1, or of any other example or embodiment described herein, wherein the first metal layer is electrically coupled with a Vdd and the second metal layer is electrically coupled with a Vss.

Example 12 may include the capacitor of example 11, or of any other example or embodiment described herein, further comprising: a third metal layer that extends from a first side of the first substrate to a second side of the first substrate opposite the first side; a fourth metal layer that extends from a first side of the second substrate to a second side of the second substrate opposite the first side; and wherein the third metal layer is electrically coupled with the first metal layer and electrically isolated from the second metal layer, and wherein the fourth metal layer is electrically coupled with the second metal layer and electrically isolated from the first metal layer.

Example 13 may include the capacitor of example 1, or of any other example or embodiment described herein, wherein the first metal layer and the second metal layer include copper.

Example 14 may include the capacitor of example 1, or of any other example or embodiment described herein, wherein the dielectric layer includes a selected one or more of: hafnium silicate, zirconium silicate, hafnium dioxide, zirconium dioxide, hafnium, zirconium, silicon nitride, silicon oxide, silicon, nitrogen, or oxygen.

Example 15 may include the capacitor of example 1, or of any other example or embodiment described herein, wherein the capacitor is a decoupling capacitor.

Example 16 is a method comprising: providing a first substrate; forming a first metal layer in the first substrate; providing a second substrate; forming a second metal layer in the second substrate; applying a dielectric layer on the first metal layer or on the second metal layer; hybrid bonding the first substrate to the second substrate, wherein the second metal layer is physically coupled with the dielectric layer, the first metal layer is physically coupled with the dielectric layer, and wherein the first metal layer and the second metal layer are electrically isolated from each other.

Example 17 may include the method of example 16, or of any other example or embodiment described herein, wherein applying the dielectric layer further includes applying the dielectric layer using a chemical vapor deposition (CVD), or atomic layer deposition (ALD) process.

Example 18 may include the method of example 16, or of any other example or embodiment described herein, wherein the first substrate is a selected one of: silicon or glass; and wherein the second substrate is a selected one of: silicon or glass.

Example 19 may include the method of example 16, or of any other example or embodiment described herein, wherein the first metal layer and the second metal layer include copper.

Example 20 may include the method of example 16, or of any other example or embodiment described herein, wherein the dielectric layer has a thickness ranging from 3 µm to 10 µm.

Example 21 is a package comprising: a multilayer substrate that includes a capacitor; a metal layer on the multilayer substrate and electrically coupled with the capacitor; and wherein the decoupling capacitor includes: a first substrate; a first metal layer in the first substrate; a second substrate; a second metal layer in the second substrate; a dielectric layer between the first metal layer and the second metal layer, wherein the first metal layer and the dielectric layer are in direct physical contact, the second metal layer and the dielectric layer are in direct physical contact, and wherein the first metal layer and the second layer are electrically isolated from each other.

Example 22 may include the package of example 21, or of any other example or embodiment described herein, wherein the first substrate and the second substrate are hybrid bonded.

Example 23 may include the package of example 21, or of any other example or embodiment described herein, wherein the dielectric is a high-k dielectric.

Example 24 may include the package of example 21, or of any other example or embodiment described herein, wherein the first metal layer and the second metal layer overlap with respect to a direction perpendicular to a plane of a side of the first substrate.

Example 25 may include the package of example 21, or of any other example or embodiment described herein, wherein the first metal layer is electrically coupled with a Vdd and the second metal layer is electrically coupled with a Vss.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

What is claimed is:

1. A capacitor comprising:
a first substrate;
a first metal layer in the first substrate;
a second substrate;
a second metal layer in the second substrate; and
a dielectric layer between the first metal layer and the second metal layer, wherein the first metal layer and the dielectric layer are in physical contact, the second metal layer and the dielectric layer are in direct physical contact, and wherein the first metal layer and the second layer are electrically isolated from each other.

2. The capacitor of claim 1,
wherein the dielectric layer is on the first metal layer in the first substrate.

3. The capacitor of claim 2, wherein a portion of the dielectric layer is on the first metal layer in the first substrate, and wherein another portion of the dielectric layer is on the second metal layer in the second substrate.

4. The capacitor of claim 1, wherein the first substrate and the second substrate are hybrid bonded.

5. The capacitor of claim 1, wherein the dielectric comprises hafnium or zirconium.

6. The capacitor of claim 1, wherein the dielectric layer has a thickness ranging from 3 µm to 10 µm.

7. The capacitor of claim 1, wherein the first substrate includes a selected one of: silicon or glass.

8. The capacitor of claim 1, wherein the first metal layer in the first substrate extends from a first side of the first substrate to a second side of the first substrate opposite the first side of the first substrate.

9. The capacitor of claim 1, wherein the first metal layer and the second metal layer overlap with respect to a direction perpendicular to a plane of a side of the first substrate.

10. The capacitor of claim 1, wherein the first metal layer or the second metal layer are dummy bond pads.

11. The capacitor of claim 1, wherein the first metal layer is electrically coupled with a Vdd and the second metal layer is electrically coupled with a Vss.

12. The capacitor of claim 11, further comprising:
a third metal layer that extends from a first side of the first substrate to a second side of the first substrate opposite the first side;
a fourth metal layer that extends from a first side of the second substrate to a second side of the second substrate opposite the first side; and
wherein the third metal layer is electrically coupled with the first metal layer and electrically isolated from the second metal layer, and wherein the fourth metal layer is electrically coupled with the second metal layer and electrically isolated from the first metal layer.

13. The capacitor of claim 1, wherein the first metal layer and the second metal layer include copper.

14. The capacitor of claim 1, wherein the dielectric layer includes a selected one or more of: hafnium silicate, zirconium silicate, hafnium dioxide, zirconium dioxide, hafnium, zirconium, silicon nitride, silicon oxide, silicon, nitrogen, or oxygen.

15. The capacitor of claim 1, wherein the capacitor is a decoupling capacitor.

16. A method comprising:
providing a first substrate;
forming a first metal layer in the first substrate;
providing a second substrate;
forming a second metal layer in the second substrate;
applying a dielectric layer on the first metal layer or on the second metal layer;
hybrid bonding the first substrate to the second substrate, wherein the second metal layer is physically coupled with the dielectric layer, the first metal layer is physically coupled with the dielectric layer, and wherein the first metal layer and the second metal layer are electrically isolated from each other.

17. The method of claim 16, wherein applying the dielectric layer further includes applying the dielectric layer using a chemical vapor deposition (CVD), or atomic layer deposition (ALD) process.

18. The method of claim 16, wherein the first substrate is a selected one of: silicon or glass; and wherein the second substrate is a selected one of: silicon or glass.

19. The method of claim 16, wherein the first metal layer and the second metal layer include copper.

20. The method of claim 16, wherein the dielectric layer has a thickness ranging from 3 µm to 10 µm.

21. A package comprising:
a multilayer substrate that includes a capacitor;
a metal layer on the multilayer substrate and electrically coupled with the capacitor; and
wherein the capacitor includes:
a first substrate;
a first metal layer in the first substrate;
a second substrate;
a second metal layer in the second substrate;
a dielectric layer between the first metal layer and the second metal layer, wherein the first metal layer and the dielectric layer are in direct physical contact, the second metal layer and the dielectric layer are in direct physical contact, and wherein the first metal layer and the second layer are electrically isolated from each other.

22. The package of claim 21, wherein the first substrate and the second substrate are hybrid bonded.

23. The package of claim 21, wherein the dielectric comprises hafnium or zirconium.

24. The package of claim 21, wherein the first metal layer and the second metal layer overlap with respect to a direction perpendicular to a plane of a side of the first substrate.

25. The package of claim 21, wherein the first metal layer is electrically coupled with a Vdd and the second metal layer is electrically coupled with a Vss.
